(19) United States
(12) Patent Application Publication
(10) Pub. No.: US 2026/0059992 A1
(43) Pub. Date: Feb. 26, 2026

(54) DISPLAY DEVICE AND ELECTRONIC DEVICE INCLUDING THE SAME

(71) Applicant: Samsung Display Co., Ltd., Yongin-si (KR)

(72) Inventors: MIKYUNG SEO, Yongin-si (KR); JONG-HWA KIM, Yongin-si (KR); HYUNGJUN PARK, Yongin-si (KR); GYEONGNAM BANG, Yongin-si (KR); CHANGHO LEE, Yongin-si (KR)

(21) Appl. No.: 19/309,479

(22) Filed: Aug. 25, 2025

(30) Foreign Application Priority Data
Aug. 26, 2024 (KR) 10-2024-0114282

(51) Int. Cl. H10K 59/80; H10K 59/38

(52) U.S. Cl. CPC H10K 59/8792; H10K 59/38

(57) ABSTRACT

A display device includes a display panel including a base substrate having a display area and a non-display area, the display area having a first area and a second area, a first unit pixel in the first area, a second unit pixel in the second area, and an encapsulation layer covering the first unit pixel and the second unit pixel, and a light control layer including a first light shielding layer in the first area and the second area, the first light shielding layer defining openings to transmit light generated by the first unit pixel and the second unit pixel, a second light shielding layer on the first light shielding layer, the second light shielding layer including light shielding patterns defining pattern openings that respectively overlap the openings in the second area, and an outer pattern in the non-display area and adjacent the light shielding patterns.

### CROSS-REFERENCE TO RELATED APPLICATION

The present application claims priority to and the benefit of Korean Patent Application No. 10-2024-0114282, filed on Aug. 26, 2024, in the Korean Intellectual Property Office, the entire disclosure of which is incorporated herein by reference.

### BACKGROUND

### A. Field

Embodiments of the present disclosure described herein relate to a display device, and for example, relate to a display device that may be operated in two modes.

### B. Description of the Related Art

Electronic devices such as smart phones, tablets, laptop computers, vehicle navigation systems, and smart televisions have been developed. These electronic devices are provided with display devices to provide information.

Users of such display devices desire devices that can display images having qualities that are appropriate or suitable for the types of situations in which the device will be used. For example, a user may want a brighter image outside a building, where the images will be affected by natural light. In some situations, a user may want a device that provides an image having a narrow viewing angle, for when personal information is viewed on the device.

The above information disclosed in this Background section is intended to enhance understanding of the background of the disclosure and may contain information that does not constitute prior art.

### SUMMARY

Aspects of one or more embodiments of the present disclosure are directed to a display device having reduced tearing defects in light shielding patterns arranged on pixels and having a narrow viewing angle.

Aspects of one or more embodiments of the present disclosure are directed to a display device having light shielding patterns that provide a narrow viewing angle and that are connected in an integral, one body shape to avoid or reduce lifting that may occur at boundaries between display and non-display areas.

Aspects of one or more embodiments of the present disclosure are directed to an electronic device including the display device.

Additional aspects will be set forth in part in the description which follows and, in part, will be apparent from the description, or may be learned by practice of the presented embodiments of the disclosure.

According to one or more embodiments, a display device includes a display panel including a base substrate including a display area and a non-display area adjacent to the display area, the display area including a first area and a second area, a first unit pixel arranged in the first area, a second unit pixel arranged in the second area, and an encapsulation layer covering the first unit pixel and the second unit pixel, and a light control layer including a first light shielding layer arranged in the first area and the second area, the first light shielding layer defining openings to transmit light generated by the first unit pixel and the second unit pixel, color filters arranged in the openings, and a second light shielding layer arranged on the first light shielding layer, wherein the second light shielding layer includes light shielding patterns defining pattern openings that respectively overlap the openings arranged in the second area, and at least one outer pattern arranged in the non-display area and adjacent to the light shielding patterns.

In one or more embodiments, the light shielding patterns and the outer pattern may be an integral pattern in which the light shielding patterns and the outer pattern are arranged on the same layer and connected to each other.

In one or more embodiments, the light shielding patterns and the outer pattern may include the same material.

In one or more embodiments, the first unit pixel may include (1-1)^{th} pixels to provide (emit) a first color light and is spaced and/or apart (e.g., spaced apart or separated) from each other in a first direction, a (1-2)^{th} pixel to provide (emit) a second color light different from the first color light and is spaced and/or apart (e.g., spaced apart or separated) from the (1-1)^{th} pixels in diagonal directions that are at an angle relative to the first direction, and a (1-3)^{th} pixel to provide (emit) a third color light different from the first color light and the second color light, is spaced and/or apart (e.g., spaced apart or separated) from the (1-2)^{th} pixel in a second direction intersecting the first direction, and are spaced part from the (1-1)^{th} pixels in the diagonal directions.

In one or more embodiments, the second unit pixel may include (2-1)^{th} pixels to provide (emit) the first color light and are spaced and/or apart (e.g., spaced apart or separated) from each other in the first direction, a (2-2)^{th} pixel to provide (emit) the second color light and is spaced and/or apart (e.g., spaced apart or separated) from the (2-1)^{th} pixels in the diagonal directions, and a (2-3)^{th} pixel to provide (emit) the third color light, is spaced and/or apart (e.g., spaced apart or separated) from the (2-2)^{th} pixel in the second direction, and is spaced and/or apart (e.g., spaced apart or separated) from the (2-1)^{th} pixels in the diagonal directions.

In one or more embodiments, the first unit pixel may be provided as (e.g., may include) a plurality of first unit pixels, and the second unit pixel may be provided as (e.g., may include) a plurality of second unit pixels, where four different second unit pixels the plurality of second unit pixels may be arranged adjacent to a first unit pixel of the plurality of first unit pixels in the diagonal directions, and four different first unit pixels may be arranged adjacent to a second unit pixel of the plurality of second unit pixels in the diagonal directions.

In one or more embodiments, the second area comprises a plurality of second areas, the light shielding patterns are arranged inside one second area of the plurality of second areas and may be spaced and/or apart (e.g., spaced apart or separated) from each other in the diagonal directions (e.g., in a first diagonal direction and a second diagonal direction), and each of the light shielding patterns may have a ring shape.

In one or more embodiments, the second light shielding layer may further include bridge patterns arranged between the light shielding patterns arranged inside the second area.

In one or more embodiments, the second light shielding layer may further include connection patterns that connect the light shielding patterns arranged on different second unit pixels of the plurality of second unit pixels, and one end of the connection pattern may be connected to the light shielding pattern arranged in one second area of the plurality of second areas, and the other end of the connection pattern may be connected to a light shielding pattern of the light shielding patterns arranged in another second area of the plurality of second areas.

In one or more embodiments, each of the (1-1)^{th} pixel, the (1-2)^{th} pixel, the (1-3)^{th} pixel, the (2-1)^{th} pixel, the (2-2)^{th} pixel, and the (2-3)^{th} pixel may include a first electrode, a second electrode, and a light-emitting pattern arranged between the first electrode and the second electrode.

In one or more embodiments, the display panel may include a pixel-defining film defining display openings exposing at least a portion of each of the first electrodes of the (1-1)^{th} pixels, the (1-2)^{th} pixel, the (1-3)^{th} pixel, the (2-1)^{th} pixels, the (2-2)^{th} pixel, and the (2-3)^{th} pixel, the light-emitting patterns of the (1-1)^{th} pixels, the (1-2)^{th} pixel, the (1-3)^{th} pixel, the (2-1)^{th} pixels, the (2-2)^{th} pixel, and the (2-3)^{th} pixel may be arranged in the display openings, and the openings and the pattern openings may overlap the display openings.

In one or more embodiments, an area of the pattern openings may be smaller than an area of the openings.

In one or more embodiments, each of the openings may have one of a circular shape and/or an elliptical shape.

In one or more embodiments, each of the pattern openings may have a circular shape.

In one or more embodiments, the base substrate may define a hole area arranged inside the display area, the display panel may define a module hole passing through the display panel and overlapping the hole area, and the display device may further include a camera module overlapping the module hole.

In one or more embodiments, the second light shielding layer may further include a hole pattern around (e.g., surrounding) the module hole, and the hole pattern may be an integral pattern in which the hole pattern and the light shielding patterns are arranged on the same layer and are connected to each other.

In one or more embodiments, the second light shielding layer may further include dummy patterns arranged in the non-display area adjacent to a boundary between the display area and the non-display area and in the hole area adjacent to a boundary between the hole area and the display area and having a shape from which some of the light shielding patterns are removed (e.g., a shape that is the same as a portion of a shape of the light shielding patterns), and the dummy patterns may be arranged between the light shielding patterns and the outer pattern and between the light shielding patterns and the hole pattern.

In one or more embodiments, the light control layer may include a planarization layer covering the color filters, the second light shielding layer being on the planarization layer, and an overcoating layer arranged on the planarization layer and covering the second light shielding layer.

In one or more embodiments, the encapsulation layer may include a first organic layer, a second organic layer, and an organic layer arranged between the first inorganic layer and the second inorganic layer.

In one or more embodiments, the display panel may further include a sensor layer directly arranged on the encapsulation layer, the sensor layer including insulating layers and conductive layers between the insulating layers.

In one or more embodiments, the first light shielding layer may be directly on an uppermost insulating layer among the insulating layers.

According to one or more embodiments, an electronic device includes a display device including a display panel including a base substrate including a display area and a non-display area adjacent to the display area, the display area including a first area and a second area, a first unit pixel arranged in the first area, a second unit pixel arranged in the second area, and an encapsulation layer covering the first unit pixel and the second unit pixel, and a light control layer including a first light shielding layer arranged in the first area and the second area, the first light shielding layer defining openings to transmit light generated by the first unit pixel and the second unit pixel, color filters arranged in the openings, and a second light shielding layer arranged on the first light shielding layer, wherein the second light shielding layer includes light shielding patterns defining pattern openings that respectively overlap the openings arranged in the second area, and at least one outer pattern arranged in the non-display area and adjacent to the light shielding patterns.

In one or more embodiments, the electronic device may be a mobile phone, a tablet, a smart watch, a laptop, a computer, or a smart television.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a plan view of a display device, according to one or more embodiments of the present disclosure.

FIG. 2 is a perspective view of the display device, according to one or more embodiments of the present disclosure.

FIG. 3 is a cross-sectional view of the display device, according to one or more embodiments of the present disclosure.

FIG. 4A is an enlarged plan view illustrating a partial area of a display area, according to one or more embodiments of the present disclosure.

FIG. 4B is an enlarged plan view illustrating a partial area of the display area, according to one or more embodiments of the present disclosure.

FIG. 5A is a cross-sectional view taken along the line I-I′ of FIG. 4A, according to one or more embodiments of the present disclosure.

FIG. 5B is a cross-sectional view taken along the line II-II′ of FIG. 4A, according to one or more embodiments of the present disclosure.

FIG. 6A is an enlarged plan view illustrating a partial area of the display area, according to one or more embodiments of the present disclosure.

FIG. 6B is an enlarged plan view illustrating a partial area of the display area, according to one or more embodiments of the present disclosure.

FIG. 7A is a plan view illustrating a second light shielding layer, according to one or more embodiments of the present disclosure.

FIG. 7B is an enlarged plan view of the area AA′ of FIG. 7A, according to one or more embodiments of the present disclosure.

FIG. 7C is an enlarged plan view of the area BB′ of FIG. 7A, according to one or more embodiments of the present disclosure.

FIG. 8 is a plan view illustrating a portion of the second light shielding layer according to one or more embodiments of the present disclosure.

FIG. 9A is a plan view illustrating a display panel according to one or more embodiments of the present disclosure.

FIG. 9B is an enlarged plan view of the area CC′ of FIG. 9A, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided. Further, in the drawings, the relative sizes (e.g., thicknesses, ratios, and dimensions) of elements, layers, and regions may be exaggerated for clarity and/or for the effective description of technical contents of the present disclosure.

As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction DR1 and the second direction DR2. This refers to that in a plan view, the arrangement of sub-pixels, pads, and other components as they are laid out on the substrate can be seen, without any perspective distortion.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, embodiments of the present disclosure will be described with reference to the accompanying drawings.

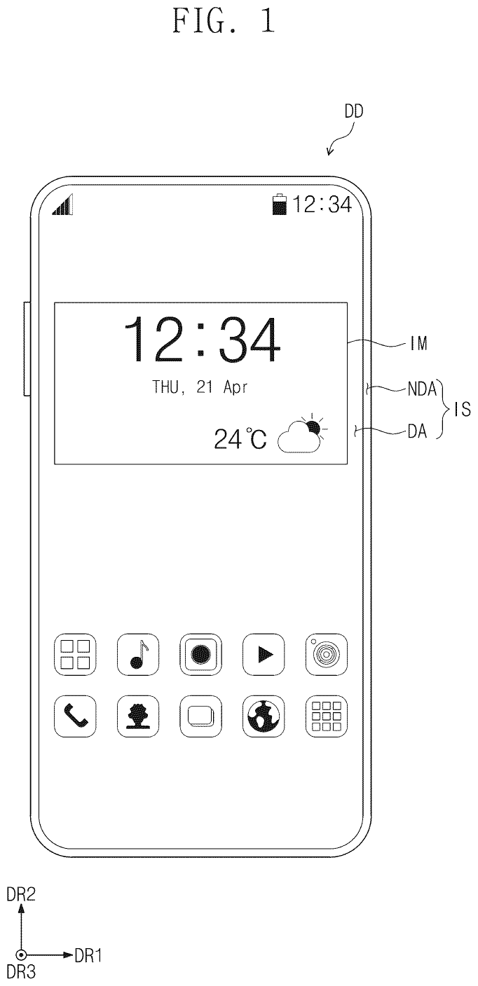

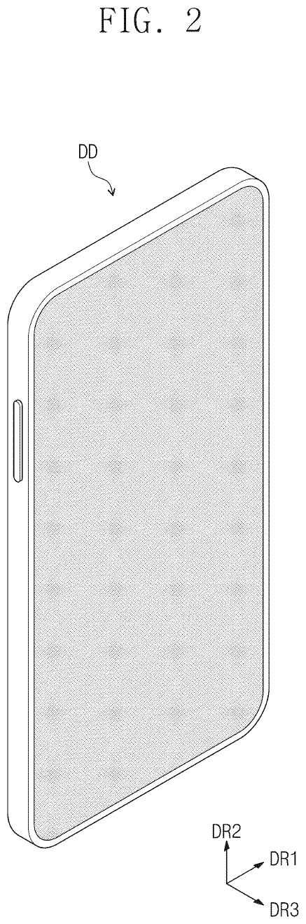

FIG. 1 is a front (plan) view of a display device according to one or more embodiments of the present disclosure. FIG. 2 is a perspective view of the display device according to one or more embodiments of the present disclosure.

Referring to FIGS. 1 and 2, a display device DD may be a device that is activated according to an electric signal. The display device DD may be applied to and included in electronic devices such as mobile phones, tablets, smart watches, laptops, computers, and smart televisions.

The display device DD may display an image on a display surface IS parallel to a first direction DR1 and a second direction DR2. The display surface IS on which the image is displayed may correspond to a front surface of the display device DD. The image may include a still image as well as a dynamic image (e.g., a video). A normal direction of the display surface IS, that is, a thickness direction of the display device DD, is indicated by a third direction DR3. Hereinafter, front surfaces (or upper surfaces) and rear surfaces (or lower surfaces) of layers or units, which will be described in more detail below, are distinguished by the third direction DR3.

The display surface IS of the display device DD may be divided into a display area DA (e.g., an active area) and a non-display area NDA (e.g., a peripheral area). The display area DA may be an area on which the image is displayed. A user may visually recognizes the image through the display area DA. In one or more embodiments, the display area DA has a quadrangular shape having rounded vertexes. However, this is an example, and the display area DA may have one or more suitable shapes. The present disclosure is not limited to any one embodiment.

The non-display area NDA is adjacent to the display area DA. The non-display area NDA may have a set or predetermined color. The non-display area NDA may be around (e.g., surround) the display area DA. Accordingly, a shape of the display area DA may be substantially defined by the non-display area NDA. However, this is an example, and the non-display area NDA may be arranged adjacent to only one side of the display area DA or may not be provided. The display device DD according to one or more embodiments of the present disclosure may include one or more suitable embodiments and is not limited to one embodiment.

FIG. 1 is a front (or plan) view of the display device DD that is operated in a first mode or a second mode. FIG. 2 is a side perspective view of the display device DD operated in the second mode. For example, the first mode may be a normal mode in which a screen is displayed at a first viewing angle, and the second mode may be a private mode in which the screen is displayed at a second viewing angle that is narrower than the first viewing angle. The first viewing angle and the second viewing angle may be defined as angles at which the user may view the image without distortion of image quality based on the normal direction of the display surface IS.

Referring to FIG. 1, in the first mode or the second mode, if (e.g., when) the display device DD is viewed from the front surface (or a direction parallel to the normal direction or the third direction DR3), images IM generated by the display device DD may be visually recognized by the user. In the second mode, if (e.g., when) the display device DD is viewed at an angle that is greater than the second viewing angle, the images IM may not be visually recognized.

The second viewing angle and luminance at the second viewing angle of the second mode may be set variously. In the first mode, if (e.g., when) the display device DD is viewed at the angle that is greater than the second viewing angle, the user may visually recognize the images IM. For example, the second viewing angle may be 45 degrees, and the luminance at 45 degrees may be 10% of the maximum luminance. In the first mode, the luminance at 45 degrees may be 20% or more. However, the present disclosure is not particularly limited thereto.

The display device DD may be selectively operated in one of the first mode, in which the screen is displayed at the first viewing angle, and the second mode, in which the screen is displayed at the second viewing angle that is smaller than the first viewing angle. In switching between the first mode and the second mode, the first mode is switched to the second mode if (e.g., when) the user changes the settings or a specific application is executed. For example, if (e.g., when) an application having a risk of personal information exposure, such as a bank application or a memo application, is executed, the display device DD may be switched from the first mode to the second mode.

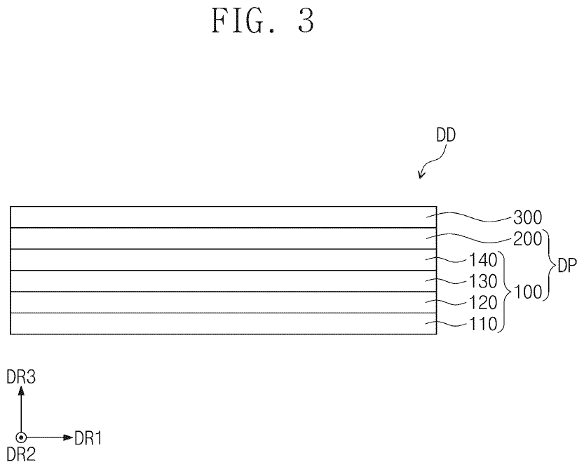

FIG. 3 is a cross-sectional view of the display device according to one or more embodiments of the present disclosure.

Referring to FIG. 3, the display device DD may include a display panel DP and a light control layer 300. In one or more embodiments, a window defining an external appearance of the display device DD may be arranged on the light control layer 300.

The display panel DP may include a display layer 100 and a sensor layer 200.

The display layer 100 may include a base layer 110, a circuit layer 120, a light-emitting element layer 130, and an encapsulation layer 140. The display layer 100 may be a component which substantially generates an image. The display layer 100 may be a light-emitting display layer. For example, the display layer 100 may be an organic light-emitting display layer, an inorganic light-emitting display layer, an organic-inorganic light-emitting display layer, a quantum dot display layer, a micro-LED display layer, or a nano-LED display layer.

The base layer 110 may be a member that provides a base surface on which the circuit layer 120 is arranged. The base layer 110 may be a glass substrate, a metal substrate, a silicon substrate, a polymer substrate, and/or the like. However, the present disclosure is not limited thereto, and the base layer 110 may be an inorganic layer, an organic layer, or a composite material layer.

The circuit layer 120 may be arranged on the base layer 110. The circuit layer 120 may include an insulating layer, a semiconductor pattern, a conductive pattern, a signal line, and/or the like. The insulating layer, a semiconductor layer, and a conductive layer are formed on the base layer 110 in a manner such as by coating and/or deposition, and thereafter, the insulating layer, the semiconductor layer, and the conductive layer may be selectively patterned through a plurality of photolithography processes. Thereafter, the semiconductor pattern, the conductive pattern, and the signal line included in the circuit layer 120 may be formed.

The light-emitting element layer 130 may be arranged on the circuit layer 120. The light-emitting element layer 130 may include a light-emitting element. For example, the light-emitting element layer 130 may include an organic light-emitting material, an inorganic light-emitting material, an organic-inorganic light-emitting material, a quantum dot, a quantum rod, a micro-LED, or a nano-LED.

The encapsulation layer 140 may be arranged on the light-emitting element layer 130. The encapsulation layer 140 may protect the light-emitting element layer 130 from moisture, oxygen, and/or foreign substances, such as dust particles. The encapsulation layer 140 may include a plurality of inorganic layers and an organic layer arranged between the inorganic layers.

The sensor layer 200 may sense an external input applied from the outside. The external input may be an input of the user. The input of the user may include one or more suitable types (kinds) of external inputs such as contact or hovering by a portion of the body of the user or a pen, light, heat, and/or pressure. The sensor layer 200 may be referred to as a sensor, an input sensing layer, or an input sensing panel. The sensor layer 200 may be formed through a substantially continuous process together with the display layer 100 and may be directly arranged on the display layer 100. However, the present disclosure is not particularly limited thereto. For example, the sensor layer 200 may be coupled to the display layer 100 through an adhesive layer. An adhesive member may include a general adhesive or a pressure-sensitive adhesive.

The light control layer 300 may be arranged on the sensor layer 200. The light control layer 300 may reduce reflectance of external light incident from the outside of the display device DD. The light control layer 300 may be directly arranged on the sensor layer 200. However, the present disclosure is not limited thereto, and the adhesive member may be arranged between the light control layer 300 and the sensor layer 200.

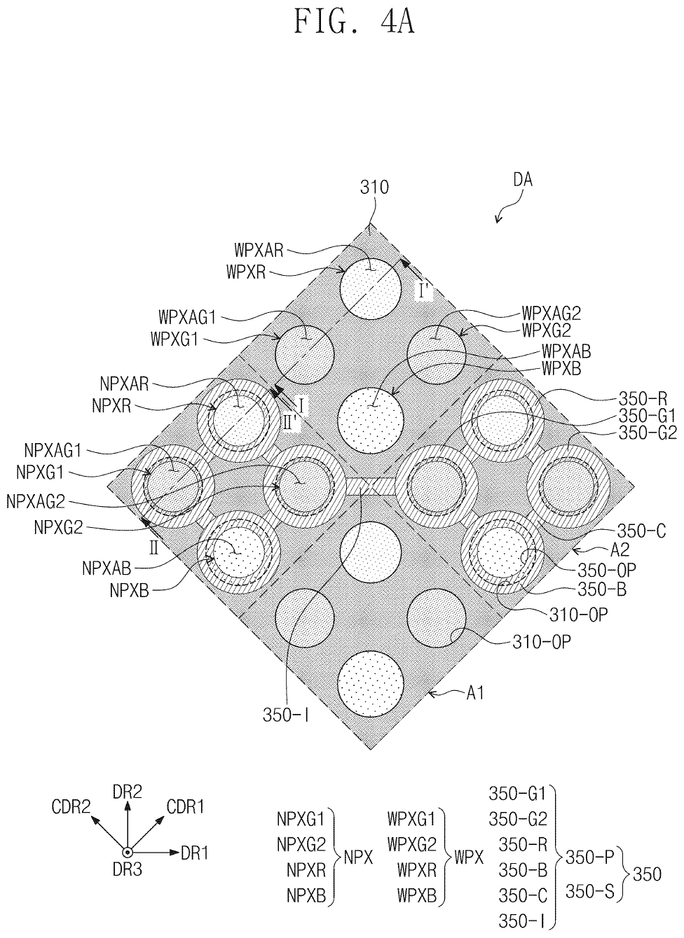

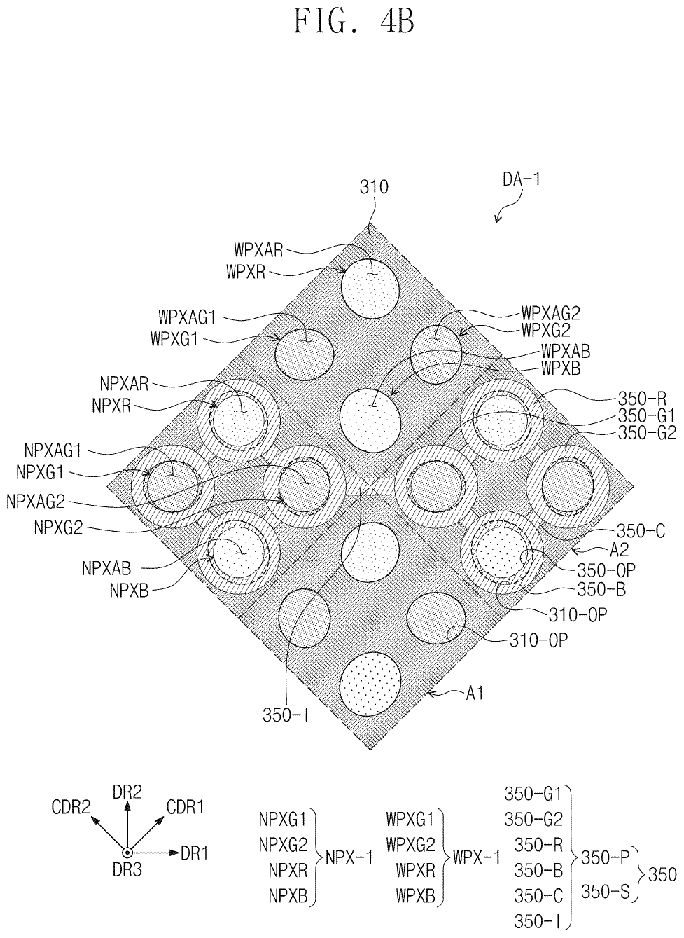

FIG. 4A is an enlarged plan view illustrating a partial area of a display area, according to one or more embodiments of the present disclosure. FIG. 4B is an enlarged plan view illustrating a partial area of the display area, according to one or more embodiments of the present disclosure.

Referring to FIG. 4A, a first unit pixel WPX and a second unit pixel NPX may be arranged in the display area DA. The first unit pixel WPX may include pixels having a relatively wide viewing angle, and the second unit pixel NPX may include pixels having a relatively narrow viewing angle.

FIG. 4A shows a portion of the display area DA, and the remaining areas of the display area DA may be configured similar to FIG. 4A with respective first and second unit pixels WPX and NPX.

According to one or more embodiments of the present disclosure, first areas A1 and second areas A2 may be arranged in the display area DA. The first areas A1 may be defined as areas in which the first unit pixels WPX is arranged, and the second areas A2 may be defined as areas in which the second unit pixels NPX is arranged. As shown in FIG. 4A, for example, one first area may include one first unit pixel WPX and one second area may include one second unit pixel NPX.

The plurality of first areas A1 and the plurality of second areas A2 may be arranged in the display area DA. The first areas A1 may be arranged to be spaced and/or apart (e.g., spaced apart or separated) from each other in the first direction DR1 and the second direction DR2. In one or more embodiments, corners of the first areas A1 may contact corners of adjacent first areas A1 in the first direction DR1 and/or the second direction DR2. The second areas A2 may be arranged to be spaced and/or apart (e.g., spaced apart or separated) from each other in the first direction DR1 and the second direction DR2. In one or more embodiments, corners of the second areas A2 may contact corners of adjacent second areas A2 in the first direction DR1 and/or the second direction DR2. According to one or more embodiments of the present disclosure, the first areas A1 and the second areas A2 may be alternately arranged in a first diagonal direction CDR1 and a second diagonal direction CDR2. The first and second diagonal directions CDR1 and CDR2 may each be at angle relative to the first and/or second directions DR1 and/or DR2. Each of the first areas A1 and the second areas A2 may be defined in a rhombus shape on a plane (e.g., in a plan view).

According to one or more embodiments, four different second areas A2 may be arranged adjacent to each other in the first diagonal direction CDR1 and the second diagonal direction CDR2 with respect to the one first area A1, and four different first areas A1 may be arranged adjacent to each other in the first diagonal direction CDR1 and the second diagonal direction CDR2 with respect to the one second area A2. Thus, another area may be arranged adjacent to one side defining the rhombus shape. For example, one first area A1 may have four sides forming a generally rhombus shape and a second area A2 may be located at each of the four sides of the first area A1, for a total of four second areas A2 around (e.g., surrounding) the first area A1. In addition, two of the four sides of the first area A1 may be arranged along the first diagonal direction CDR1 and two of the four sides may be arranged along the second diagonal direction CDR2. Further, one second area A2 may have four sides forming a generally rhombus shape and a first area A1 may be located at each of the four sides of the second area A2, for a total of four first areas A1 around (e.g., surrounding) the second area A2. In addition, two of the four sides of the second area A2 may be arranged along the first diagonal direction CDR1 and two of the four sides may be arranged along the second diagonal direction CDR2.

The first unit pixel WPX may include (1-1)^{th} pixels WPXG1 and WPXG2, a (1-2)^{th} pixel WPXR, and a (1-3)^{th} pixel WPXB. The (1-1)^{th} pixels WPXG1 and WPXG2 may provide (may be to emit) a first color light. The (1-1)^{th} pixels WPXG1 and WPXG2 may be arranged in the first direction DR1.

The (1-2)^{th} pixel WPXR may provide (may be to emit) a second color light different from the first color light. The (1-2)^{th} pixel WPXR may be spaced and/or apart (e.g., spaced apart or separated) from the one (1-1)^{th} pixel WPXG1 in the first diagonal direction CDR1 and may be spaced and/or apart (e.g., spaced apart or separated) from the other one (1-1)^{th} pixel WPXG2 in the second diagonal direction CDR2.

The (1-3)^{th} pixel WPXB may provide (may be to emit) a third color light different from the first color light and the second color light. The (1-3)^{th} pixel WPXB may be spaced and/or apart (e.g., spaced apart or separated) from the one (1-1)^{th} pixel WPXG1 in the second diagonal direction CDR2 and may be spaced and/or apart (e.g., spaced apart or separated) from the other one (1-1)^{th} pixel WPXG2 in the first diagonal direction CDR1.

The second unit pixel NPX may include (2-1)^{th} pixels NPXG1 and NPXG2, a (2-2)^{th} pixel NPXR, and a (2-3)^{th} pixel NPXB. The (2-1)^{th} pixels NPXG1 and NPXG2 may provide the first color light. The (2-1)^{th} pixels NPXG1 and NPXG2 may be arranged in the first direction DR1.

The (2-2)^{th} pixel NPXR may provide the second color light. The (2-2)^{th} pixel NPXR may be spaced and/or apart (e.g., spaced apart or separated) from the one (2-1)^{th} pixel NPXG1 in the first diagonal direction CDR1 and may be spaced and/or apart (e.g., spaced apart or separated) from the other one (2-1)^{th} pixel NPXG2 in the second diagonal direction CDR2.

The (2-3)^{th} pixel NPXB may provide the third color light. The (2-3)^{th} pixel NPXB may be spaced and/or apart (e.g., spaced apart or separated) from the one (2-1)^{th} pixel NPXG1 in the second diagonal direction CDR2 and may be spaced and/or apart (e.g., spaced apart or separated) from the other one (2-1)^{th} pixel NPXG2 in the first diagonal direction CDR1.

In one or more embodiments, the first color light may be green, the second color light may be red, and the third color light may be blue. According to one or more embodiments, each of the first unit pixel WPX and the second unit pixel NPX may include one red pixel, one blue pixel, and two green pixels. However, this is merely an example, and the number of pixels may be different from the above example.

Areas through which the lights provided from the (1-1)^{th} pixels WPXG1 and WPXG2 may be visually recognized by the user may be defined as (1-1)^{th} transmissive areas WPXAG1 and WPXAG2. An area through which the light provided from the (1-2)^{th} pixel WPXR may be visually recognized by the user may be defined as a (1-2)^{th} transmissive area WPXAR. An area through which the light provided from the (1-3)^{th} pixel WPXB may be visually recognized by the user may be defined as a (1-3)^{th} transmissive area WPXAB.

Areas through which the lights provided from the (2-1)^{th} pixels NPXG1 and NPXG2 may be visually recognized by the user may be defined as (2-1)^{th} transmissive areas NPXAG1 and NPXAG2. An area through which the light provided from the (2-2)^{th} pixel NPXR may be visually recognized by the user may be defined as a (2-2)^{th} transmissive area NPXAR. An area through which the light provided from the (2-3)^{th} pixel NPXB may be visually recognized by the user may be defined as a (2-3)^{th} transmissive area NPXAB.

According to one or more embodiments, among the transmissive areas defined in the first area A1 and the second area A2, areas of the transmissive areas WPXAR and NPXAR that provide the red light may be greater than areas of the transmissive areas WPXAG1, WPXAG2, NPXAG1, and NPXAG2 that provide the green light and may be smaller than areas of the transmissive areas WPXAB and NPXAB that provide the blue light. For example, each of the transmissive areas WPXAR and NPXAR may be larger than each of the transmissive areas WPXAG1, WPXAG2, NPXAG1, and NPXAG2 and may be smaller than each of the transmissive areas WPXAB and NPXAB.

However, the present disclosure is not limited thereto, the areas of the transmissive areas WPXAG1, WPXAG2, WPXAR, and WPXAB defined in the first area A1 may be the same, the areas of the transmissive areas NPXAG1, NPXAG2, NPXAR, and NPXAB defined in the second area A2 may be the same, and the present disclosure is not limited to one embodiment.

According to one or more embodiments of the present disclosure, the light control layer 300 (see, e.g., FIG. 3) may include a first light shielding layer 310 and a second light shielding layer 350. The transmissive areas WPXAG1, WPXAG2, WPXAR, and WPXAB in the first area A1 may be defined by openings 310-OP included in the first light shielding layer 310 overlapping the first area A1, and the transmissive areas NPXAG1, NPXAG2, NPXAR, and NPXAB in the second area A2 may be defined by pattern openings 350-OP included in a first pattern 350-P of the second light shielding layer 350.

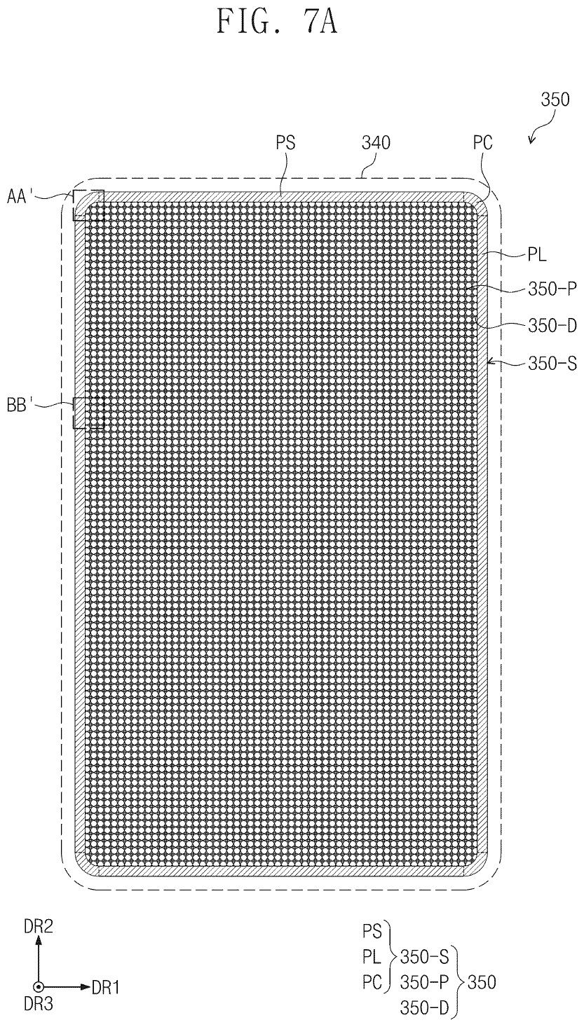

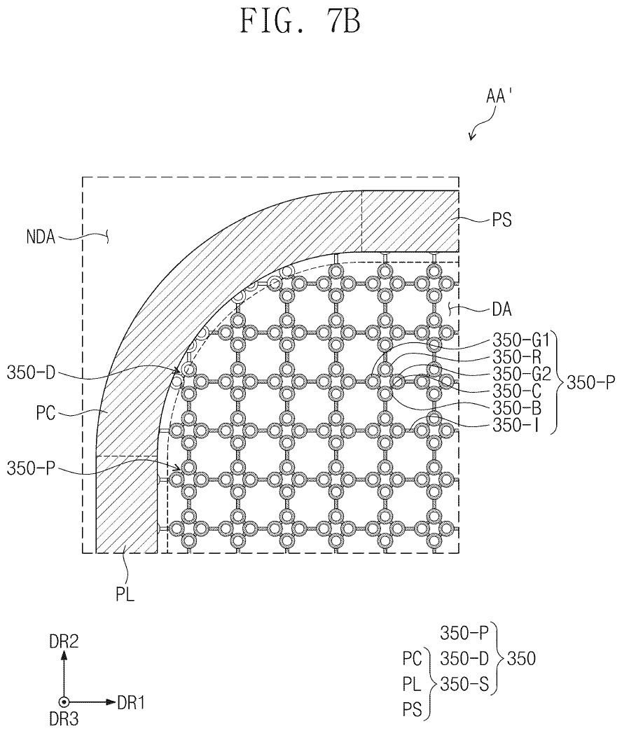

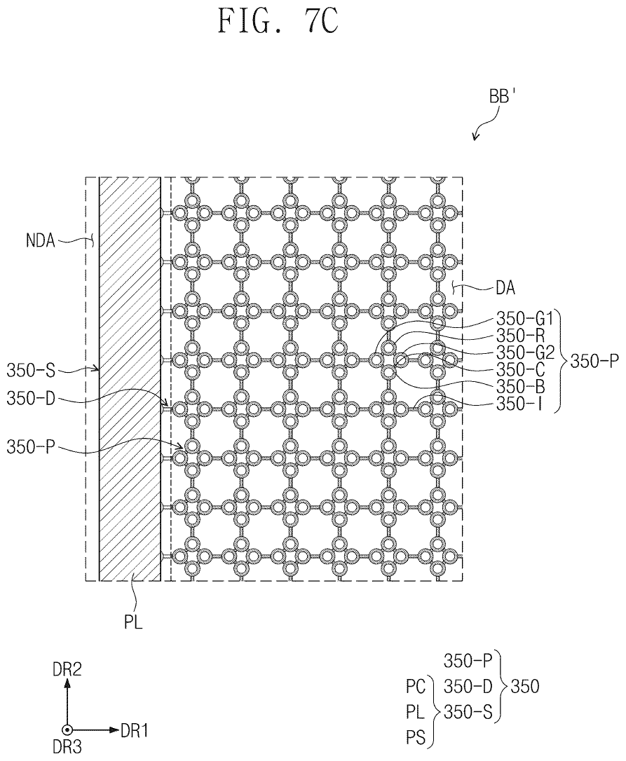

According to one or more embodiments of the present disclosure, the first light shielding layer 310 may be arranged on the entire first area A1 and the entire second area A2. The second light shielding layer 350 may be arranged only in the second areas A2. The second light shielding layer 350 may include the first pattern 350-P and a second pattern 350-S (also referred to as an “outer pattern”). The first pattern 350-P may be a portion of the second light shielding layer 350, which is arranged in the display area DA, and the second pattern 350-S may be a portion of the second light shielding layer 350, which is arranged in the non-display area NDA. The second pattern 350-S will be described with reference to FIGS. 7A to 7C.

The first pattern 350-P may include a first light shielding pattern 350-G1, a second light shielding pattern 350-G2, a third light shielding pattern 350-R, a fourth light shielding pattern 350-B, bridge patterns 350-C, and a connection pattern 350-I. The first light shielding pattern 350-G1, the second light shielding pattern 350-G2, the third light shielding pattern 350-R, and the fourth light shielding pattern 350-B may include the pattern openings 350-OP that overlap the openings 310-OP of the first light shielding layer 310 in one-to-one correspondence.

The connection pattern 350-I may be a pattern that connects different second areas A2 spaced and/or apart (e.g., spaced apart or separated) from each other in the first direction DR1 or the second direction DR2. In one or more embodiments, the connection pattern 350-I may be a pattern that connects different second areas A2 whose corners are adjacent to each other, for example, in the first direction DR1 or the second direction DR2. For example, the connection pattern 350-I may be arranged between the second light shielding pattern 350-G2 arranged in the second area A2 on the left side and the first light shielding pattern 350-G1 arranged in the second area A2 on the right side as shown, for example, in FIG. 4A.

For convenience of description, FIG. 4A illustrates the one connection pattern 350-I, but the connection patterns 350-I to be connected to the second areas A2 spaced and/or apart (e.g., spaced apart or separated) from each other (and/or adjacent to each other) in the first direction DR1 and/or the second direction DR2 may be connected to the first light shielding pattern 350-G1, the second light shielding pattern 350-G2, the third light shielding pattern 350-R, and the fourth light shielding pattern 350-B arranged inside the one second area A2. For example, a connection pattern 350-I may connect the third light shielding pattern 350-R and the fourth light shielding pattern 350-B of adjacent second areas A2 in the second direction DR2 and another connection pattern 350-I may connect the first light shielding pattern 350-G1 and the second light shielding pattern 350-G2 of adjacent second areas A2 in the first direction DR1. This configuration may be the same throughout the display area DA.

According to one or more embodiments, the openings 310-OP defined in the first light shielding layer 310 may have a circular shape. Thus, the transmissive areas WPXAG1, WPXAG2, WPXAR, and WPXAB defined in the first areas A1 may have a circular shape on a plane (e.g., in a plan view).

The pattern openings 350-OP defined in the light shielding patterns of the second light shielding layer 350 may have a circular shape. Thus, the transmissive areas NPXAG1, NPXAG2, NPXAR, and NPXAB defined in the second areas A2 may have a circular shape on a plane (e.g., in a plan view).

According to one or more embodiments, an area of the opening 310-OP may be greater than an area of the pattern opening 350-OP. Thus, areas of the transmissive areas WPXAG1, WPXAG2, WPXAR, and WPXAB defined in the first area A1 may be greater than areas of the transmissive areas NPXAG1, NPXAG2, NPXAR, and NPXAB defined in the second area A2. In FIG. 4A, the openings 310-OP in the second area A2 are illustrated as dotted lines.

In the display device DD (see, e.g., FIG. 2) according to one or more embodiments of the present disclosure, in the private mode that is the second mode, a light may not be provided to the transmissive areas defined in the first areas A1, and a light may be provided only to the transmissive areas defined in the second areas A2. Thus, in the second mode, if (e.g., when) the display device DD is viewed at an angle that is greater than a certain viewing angle, the images IM (see, e.g., FIG. 1) may not be visually recognized.

FIG. 4B will be described while focusing on differences from FIG. 4A. Redundant descriptions may not be provided.

Referring to FIG. 4B, a first unit pixel WPX-1 and a second unit pixel NPX-1 may be arranged in a display area DA-1. The first unit pixel WPX-1 may include pixels having a relatively wide viewing angle, and the second unit pixel NPX-1 may include pixels having a relatively narrow viewing angle.

According to one or more embodiments of the present disclosure, the first areas A1 and the second areas A2 may be arranged in the display area DA-1. The one first area A1 may be defined as an area in which the one first unit pixel WPX-1 is arranged, and the one second area A2 may be defined as an area in which the one second unit pixel NPX-1 is arranged.

The first unit pixel WPX-1 may include the (1-1)^{th} pixels WPXG1 and WPXG2, the (1-2)^{th} pixel WPXR, and the (1-3)^{th} pixel WPXB. The second unit pixel NPX-1 may include the (2-1)^{th} pixels NPXG1 and NPXG2, the (2-2)^{th} pixel NPXR, and the (2-3)^{th} pixel NPXB.

According to one or more embodiments of the present disclosure, the light control layer 300 (see, e.g., FIG. 3) may include the first light shielding layer 310 and the second light shielding layer 350. The transmissive areas WPXAG1, WPXAG2, WPXAR, and WPXAB in the first area A1 may be defined by the openings 310-OP included in the first light shielding layer 310 overlapping the first area A1, and the transmissive areas NPXAG1, NPXAG2, NPXAR, and NPXAB in the second area A2 may be defined by the pattern openings 350-OP included in the first pattern 350-P of the second light shielding layer 350.

According to one or more embodiments of the present disclosure, the first light shielding layer 310 may be arranged on the entire first area A1 and the entire second area A2. The second light shielding layer 350 may be arranged only in the second areas A2. The second light shielding layer 350 may include the first pattern 350-P and the second pattern 350-S.

The first pattern 350-P may include the first light shielding pattern 350-G1, the second light shielding pattern 350-G2, the third light shielding pattern 350-R, the fourth light shielding pattern 350-B, the bridge patterns 350-C, and the connection pattern 350-I. The first light shielding pattern 350-G1, the second light shielding pattern 350-G2, the third light shielding pattern 350-R, and the fourth light shielding pattern 350-B may include the pattern openings 350-OP that overlap the openings 310-OP of the first light shielding layer 310 in one-to-one correspondence.

According to one or more embodiments, shapes of the openings 310-OP defined in the first light shielding layer 310 and shapes of the pattern openings 350-OP defined in the first light shielding pattern 350-G1, the second light shielding pattern 350-G2, the third light shielding pattern 350-R, and the fourth light shielding pattern 350-B may be different from each other. For example, the openings 310-OP defined in the first light shielding layer 310 may have an elliptical shape.

Thus, the transmissive areas WPXAG1, WPXAG2, WPXAR, and WPXAB defined in the first areas A1 may have an elliptical shape on a plane (e.g., in a plan view). The elliptical shape of the openings 310-OP may be an elliptical shape having a set or predetermined rule or a random elliptical shape.

The pattern openings 350-OP defined in the first light shielding pattern 350-G1, the second light shielding pattern 350-G2, the third light shielding pattern 350-R, and the fourth light shielding pattern 350-B may have a circular shape. Thus, the transmissive areas NPXAG1, NPXAG2, NPXAR, and NPXAB defined in the second areas A2 may have a circular shape on a plane (e.g., in a plan view).

However, the present disclosure is not limited thereto, the pattern openings 350-OP defined in the first light shielding pattern 350-G1, the second light shielding pattern 350-G2, the third light shielding pattern 350-R, and the fourth light shielding pattern 350-B may have elliptical shapes corresponding to the openings 310-OP that they respectively overlap, and the present disclosure is not limited to one embodiment.

According to one or more embodiments, the area of the opening 310-OP may be greater than the area of the pattern opening 350-OP. Thus, the areas of the transmissive areas WPXAG1, WPXAG2, WPXAR, and WPXAB defined in the first area A1 may be greater than the areas of the transmissive areas NPXAG1, NPXAG2, NPXAR, and NPXAB defined in the second area A2. The openings 310-OP defined in the second area A2 are indicated by dotted lines.

According to one or more embodiments, among the transmissive areas defined in the first area A1 and the second area A2, areas of the transmissive areas WPXAR and NPXAR that provide the red light may be greater than areas of the transmissive areas WPXAG1, WPXAG2, NPXAG1, and NPXAG2 that provide the green light and may be smaller than areas of the transmissive areas WPXAB and NPXAB that provide the blue light. For example, each of the transmissive areas WPXAR and NPXAR may be larger than each of the transmissive areas WPXAG1, WPXAG2, NPXAG1, and NPXAG2 and may be smaller than each of the transmissive areas WPXAB and NPXAB.

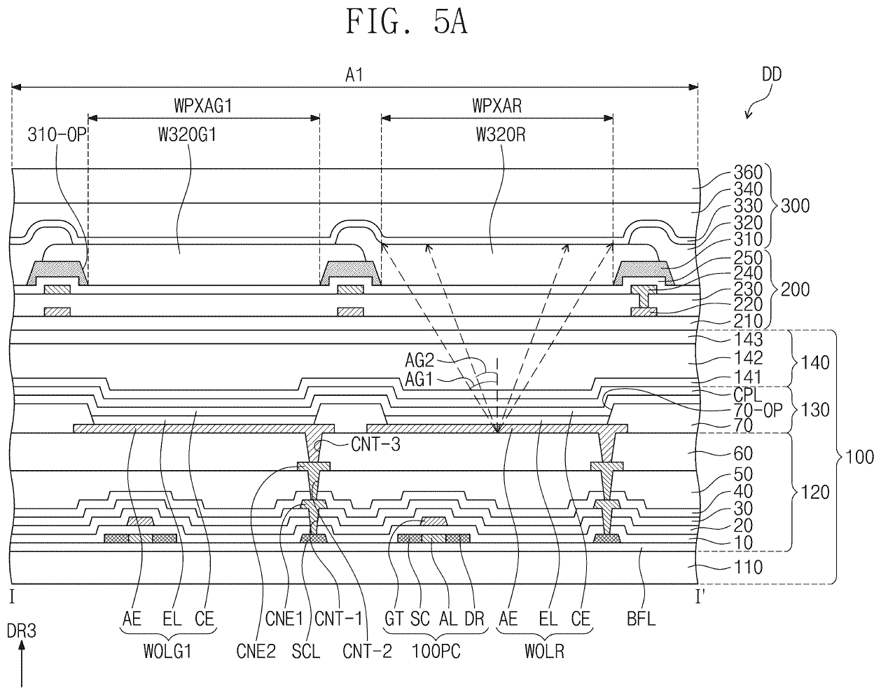

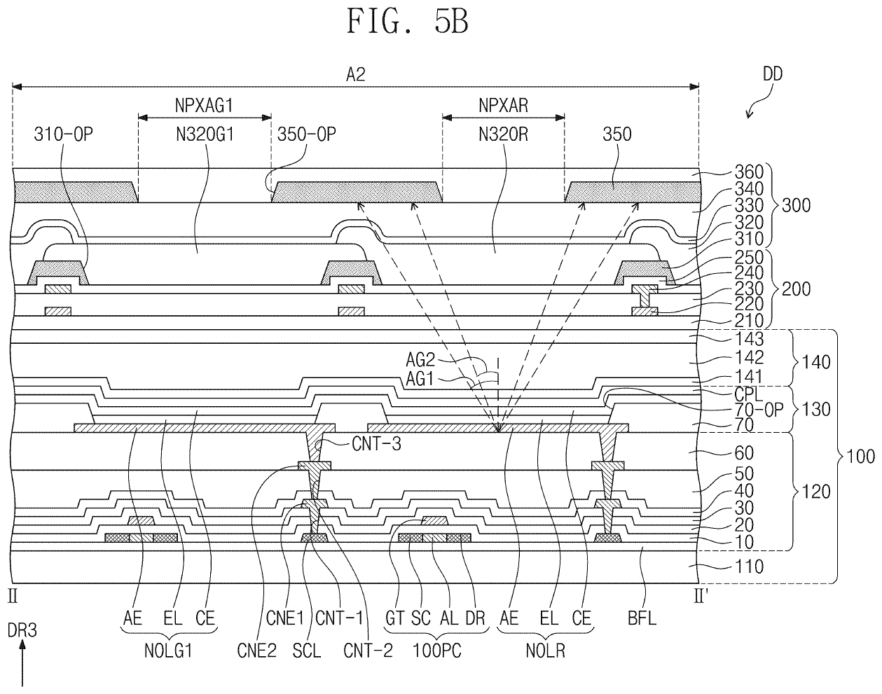

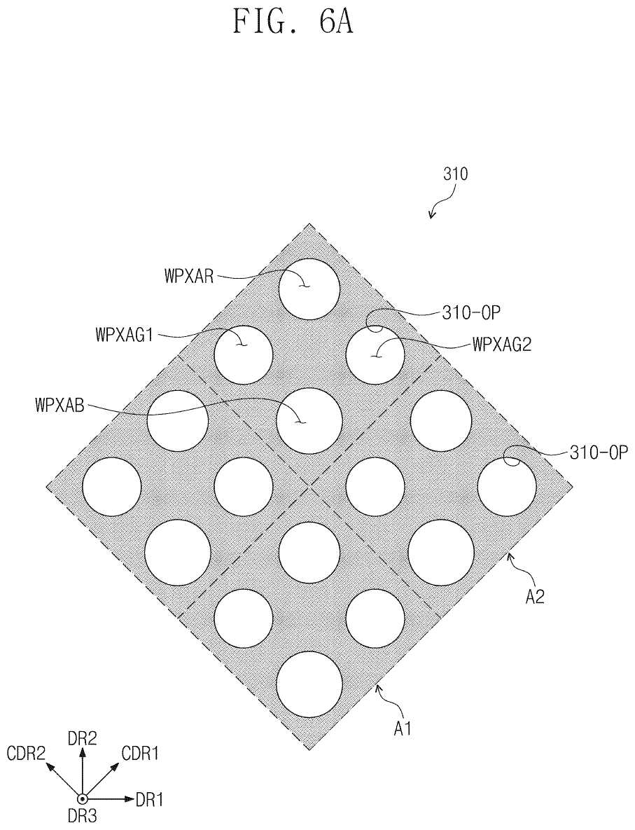

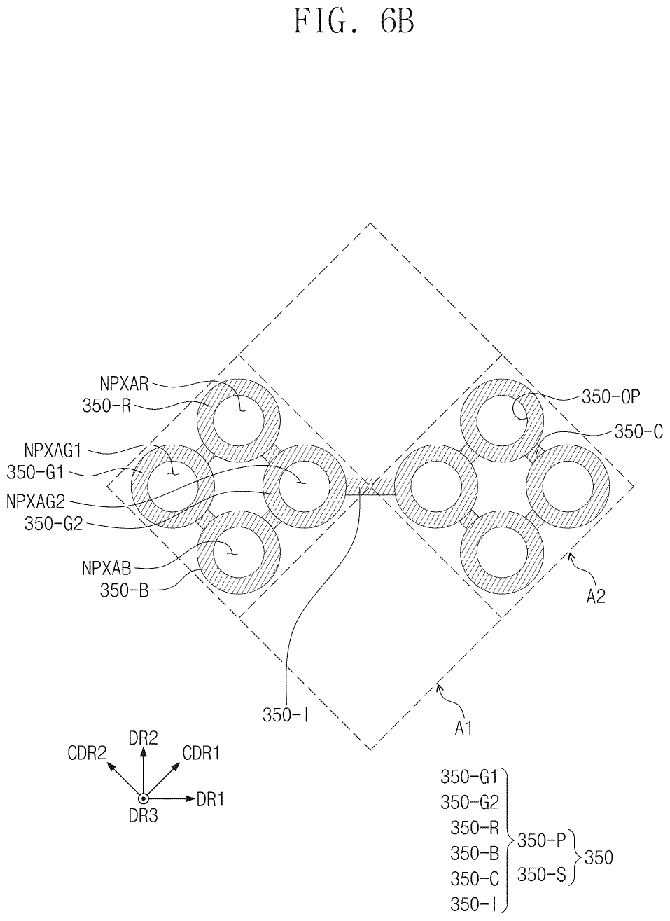

FIG. 5A is a cross-sectional view taken along the line I-I′ of FIG. 4A, according to one or more embodiments of the present disclosure. FIG. 5B is a cross-sectional view taken along the line II-II′ of FIG. 4A, according to one or more embodiments of the present disclosure. FIG. 6A is an enlarged plan view illustrating a partial area of the display area, according to one or more embodiments of the present disclosure. FIG. 6B is an enlarged plan view illustrating a partial area of the display area, according to one or more embodiments of the present disclosure. FIG. 7A is a plan view illustrating a second light shielding layer, according to one or more embodiments of the present disclosure. FIG. 7B is an enlarged plan view of the area AA′ of FIG. 7A, according to one or more embodiments of the present disclosure. FIG. 7C is an enlarged plan view of the area BB′ of FIG. 7A, according to one or more embodiments of the present disclosure.

FIG. 5A is a cross-sectional view of the first area A1 of the display device DD, and FIG. 5B is a cross-sectional view of the second area A2 of the display device DD.

Referring to FIGS. 5A and 5B, at least one inorganic layer is formed on an upper surface of the base layer 110. The inorganic layer may include at least one of an aluminum oxide, a titanium oxide, a silicon oxide, a silicon nitride, a silicon oxynitride, a zirconium oxide, and/or a hafnium oxide. The inorganic layer may be formed in multiple layers. The multi-layered inorganic layers may constitute a barrier layer and/or a buffer layer. In one or more embodiments, it is illustrated that the display layer 100 includes a buffer layer BFL.

The buffer layer BFL may improve a coupling force between the base layer 110 and the semiconductor pattern. The buffer layer BFL may include at least one of a silicon oxide, a silicon nitride, and/or a silicon oxynitride. For example, the buffer layer BFL may include a structure in which silicon oxide layers and silicon nitride layers are alternately laminated.

The semiconductor pattern may be arranged on the buffer layer BFL. The semiconductor pattern may include polysilicon. However, the present disclosure is not limited thereto, and the semiconductor pattern may include amorphous silicon, low-temperature polycrystalline silicon, and/or an oxide semiconductor.

FIGS. 5A and 5B merely illustrate a portion of the semiconductor pattern, and the semiconductor pattern may be further arranged in other areas. The semiconductor pattern may be arranged according to a specific rule or pattern across pixels. The semiconductor pattern may have a different electrical property depending on whether or not the semiconductor pattern is doped. The semiconductor pattern may include a first area having higher conductivity and a second area having lower conductivity. The first area may be doped with an N-type (kind) dopant or a P-type (kind) dopant. A P-type (kind) transistor may include a doped area doped with the P-type (kind) dopant, and an N-type (kind) transistor may include a doped area doped with the N-type (kind) dopant. The second area may be a non-doped area or may be an area doped at a concentration that is lower than a concentration of the first area.

A conductivity of the first area is greater than a conductivity of the second area, and the first area may substantially serve as an electrode or a signal line. The second area may substantially correspond to an active area (or a channel) of a transistor. For example, a portion of the semiconductor pattern may be an active area of the transistor, another portion of the semiconductor pattern may be a source area or a drain area of the transistor, and still another portion of the semiconductor pattern may be a connection electrode or a connection signal line.

Each of the pixels may include a pixel circuit and a light-emitting element. The pixel circuit may include a plurality of transistors and at least one capacitor. FIGS. 5A and 5B illustrate a transistor 100PC as an example of one of the plurality of transistors.

A source area SC, an active area AL, and a drain area DR of the transistor 100PC may be formed from the semiconductor pattern. The source area SC and the drain area DR may extend from the active area AL in opposite directions in a cross-section (e.g., along the first or second direction DR1 or DR2). FIGS. 5A and 5B illustrate a portion of a connection signal line SCL formed from the semiconductor pattern. In one or more embodiments, the connection signal line SCL may be connected to the drain area DR of the transistor 100PC on a plane (e.g., in a plan view).

A first insulating layer 10 may be arranged on the buffer layer BFL. The first insulating layer 10 may commonly overlap the plurality of pixels and cover the semiconductor pattern. The first insulating layer 10 may be an inorganic layer and/or an organic layer and may have a single-layer structure or a multi-layer structure. The first insulating layer 10 may include at least one of an aluminum oxide, a titanium oxide, a silicon oxide, a silicon nitride, a silicon oxynitride, a zirconium oxide, and/or a hafnium oxide. In one or more embodiments, the first insulating layer 10 may be a single-layer silicon oxide layer. The first insulating layer 10 and an insulating layer of the circuit layer 120, which will be described in more detail below, may be an inorganic layer and/or an organic layer and may have a single-layer structure or a multi-layer structure. The inorganic layer may include at least one of the above-described materials, but the present disclosure is not limited thereto.

A gate GT of each of the transistors 100PC is arranged on the first insulating layer 10. The gate GT may be a portion of a metal pattern. The gate GT overlaps the active area AL. The gate GT may function as a mask in a process of doping the semiconductor pattern.

A second insulating layer 20 may be arranged on the first insulating layer 10 and may cover the gate GT. The second insulating layer 20 may commonly overlap the pixels (e.g., may cover and/or overlap all the pixels as one common layer). The second insulating layer 20 may be an inorganic layer and/or an organic layer and may have a single-layer structure or a multi-layer structure. The second insulating layer 20 may include at least one of a silicon oxide, a silicon nitride, and/or a silicon oxynitride. In one or more embodiments, the second insulating layer 20 may have a multi-layer structure including a silicon oxide layer and a silicon nitride layer.

A third insulating layer 30 may be arranged on the second insulating layer 20. The third insulating layer 30 may have a single-layer structure or a multi-layer structure. For example, the third insulating layer 30 may have a multi-layer structure including a silicon oxide layer and a silicon nitride layer.

A first connection electrode CNE1 may be arranged on the third insulating layer 30. The first connection electrode CNE1 may be connected to the connection signal line SCL through a contact hole CNT-1 passing through the first insulating layer 10, the second insulating layer 20, and the third insulating layer 30.

A fourth insulating layer 40 may be arranged on the third insulating layer 30. The fourth insulating layer 40 may be a single-layer silicon oxide layer. A fifth insulating layer 50 may be arranged on the fourth insulating layer 40. The fifth insulating layer 50 may be an organic layer.

A second connection electrode CNE2 may be arranged on the fifth insulating layer 50. The second connection electrode CNE2 may be connected to the first connection electrode CNE1 through a contact hole CNT-2 passing through the fourth insulating layer 40 and the fifth insulating layer 50.

A sixth insulating layer 60 may be arranged on the fifth insulating layer 50 and may cover the second connection electrode CNE2. The sixth insulating layer 60 may be an organic layer.

The light-emitting element layer 130 may be arranged on the circuit layer 120. The (1-1)^{th} pixel WPXG1 and the (1-2)^{th} pixel WPXR included in the first unit pixel WPX may be arranged in the light-emitting element layer 130 overlapping the first area A1, and the (2-1)^{th} pixel NPXG1 and the (2-2)^{th} pixel NPXR included in the second unit pixel NPX may be arranged in the light-emitting element layer 130 overlapping the second area A2. The structure of the (1-3)^{th} pixel WPXB and the (2-3)^{th} pixel NPXB described in FIG. 4A may be the same or substantially the same in a cross-section as the the pixels described with reference to FIGS. 5A and 5B, which will be described in more detail below.

Each of light-emitting elements WOLG1 and WOLR included in the (1-1)^{th} pixel WPXG1 and the (1-2)^{th} pixel WPXR, respectively, and light-emitting elements NOLG1 and NOLR included in the (2-1)^{th} pixel NPXG1 and the (2-2)^{th} pixel NPXR, respectively, may include a first electrode AE, a light-emitting pattern EL, and a second electrode CE. The second electrode CE may be formed on the entire first area A1 and the entire second area A2 (e.g., may cover and/or overlap the entirety of the first area A1 and the second area A2 as one common layer). Thus, the second electrode CE may be a common electrode.

The first electrode AE may be arranged on the sixth insulating layer 60. The first electrode AE may be connected to the second connection electrode CNE2 through a contact hole CNT-3 defined in the sixth insulating layer 60.

A pixel-defining film 70 may be arranged on the sixth insulating layer 60 and may cover a portion of the first electrode AE. A display opening 70-OP, through which at least a portion of the first electrode AE is exposed, is defined in the pixel-defining film 70.

The light-emitting pattern EL may be arranged inside the display opening 70-OP. The light-emitting pattern EL may be individually patterned for each of the pixels. The individually patterned light-emitting patterns EL may be to emit different lights. However, the present disclosure is not limited thereto, and the light-emitting patterns EL may be connected to each other and commonly included in the plurality of light-emitting elements. In such embodiments, the light-emitting patterns EL may provide a blue light or a white light.

The second electrode CE may be arranged on the light-emitting patterns EL. The second electrode CE may have an integral shape and may be commonly included in the plurality of pixels (e.g., may cover and/or overlap all the pixels as one common layer).

A hole control layer may be arranged between the first electrodes EL and the light-emitting patterns EL. The hole control layer may include a hole transport layer and may further include a hole injection layer. An electron control layer may be arranged between the light-emitting patterns EL and the second electrode CE. The electron control layer may include an electron transport layer and may further include an electron injection layer. The hole control layer and the electron control layer may be commonly formed at (in) the plurality of pixels (e.g., each may cover and/or overlap all the pixels as one common layer) by using an open mask or an inkjet process.

The display device DD according to one or more embodiments may include a protective layer CPL arranged on the second electrode CE. The protective layer CPL may be formed on the entire first area A1 and the entire second area A2 (e.g., may cover and/or overlap the entirety of the first area A1 and the second area A2 as one common layer). Thus, the protective layer CPL may be a common electrode. The protective layer CPL may function to protect components included in the light-emitting elements WOLG1, WOLR, NOLG1, and NOLR in a subsequent process. A refractive index of the protective layer CPL may be 2.0.

The encapsulation layer 140 may be arranged on the light-emitting element layer 130. The encapsulation layer 140 may include a first inorganic layer 141, an organic layer 142, and a second inorganic layer 143 that are sequentially laminated, but layers constituting the encapsulation layer 140 are not limited thereto. The first inorganic layer 141 and the second inorganic layer 143 may protect the light-emitting element layer 130 from moisture and/or oxygen, and the organic layer 142 may protect the light-emitting element layer 130 from foreign substances, such as dust particles. The first inorganic layer 141 and the second inorganic layer 143 may include inorganic materials. For example, each of the first inorganic layer 141 and the second inorganic layer 143 may include at least one of a silicon nitride, a silicon oxynitride, a silicon oxide, a titanium oxide, and/or an aluminum oxide. The organic layer 142 may include an acryl-based organic layer, but the present disclosure is not particularly limited thereto.

The sensor layer 200 may be directly arranged on the display layer 100. The sensor layer 200 may be formed on the display layer 100 through a substantially continuous process. The sensor layer 200 may be referred to as a sensor, an input sensing layer, or an input sensing panel. The sensor layer 200 may include a sensor base layer 210, a first conductive layer 220, an intermediate insulating layer 230, a second conductive layer 240, and a sensor cover layer 250.

The sensor base layer 210 may be arranged directly on the display layer 100 (e.g., may be arranged directly on the encapsulation layer 140 of the display layer 100). The sensor base layer 210 may be an inorganic layer including at least one of a silicon nitride, a silicon oxynitride, and/or a silicon oxide. In one or more embodiments, the sensor base layer 210 may be an organic layer including an epoxy resin, an acrylic resin, or an imide-based resin. The sensor base layer 210 may have a single-layer structure or have a multi-layer structure in which layers are laminated in the third direction DR3.

Each of the first conductive layer 220 and the second conductive layer 240 may have a single-layer structure or have a multi-layer structure in which layers are laminated in the third direction DR3.

The conductive layer having a single-layer structure may include a metal layer or a transparent conductive layer. The metal layer may include molybdenum (Mo), silver (Ag), titanium (Ti), copper (Cu), aluminum (Al), or one or more suitable alloys thereof. The transparent conductive layer may include a transparent conductive oxide such as an indium tin oxide, an indium zinc oxide, a zinc oxide, or an indium zinc tin oxide. In one or more embodiments, the transparent conductive layer may include a conductive polymer such as poly(3,4-ethylenedioxythiophene) (PEDOT), a metal nanowire, graphene, and/or the like.

The conductive layer having a multi-layer structure may include metal layers. The metal layers may have, for example, a three-layer structure of titanium/aluminum/titanium. The conductive layer having a multi-layer structure may include at least one metal layer and at least one transparent conductive layer.

The intermediate insulating layer 230 may be arranged between the first conductive layer 220 and the second conductive layer 240. The intermediate insulating layer 230 may include an inorganic layer. The inorganic film may include at least one of an aluminum oxide, a titanium oxide, a silicon oxide, a silicon nitride, a silicon oxynitride, a zirconium oxide, and/or a hafnium oxide.

In one or more embodiments, the intermediate insulating layer 230 may include an organic film. The organic film may include at least one of an acryl-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, and/or a perylene-based resin.

The sensor cover layer 250 may be arranged on the intermediate insulating layer 230 and may cover the second conductive layer 240. The second conductive layer 240 may include a conductive pattern. The sensor cover layer 250 may cover the conductive pattern to reduce or eliminate a probability of causing damage to the conductive pattern in a subsequent process. The sensor cover layer 250 may include an inorganic material. For example, the sensor cover layer 250 may include a silicon nitride, but the present disclosure is not particularly limited thereto. In one or more embodiments of the present disclosure, the sensor cover layer 250 may not be provided.

The light control layer 300 may be arranged on the sensor layer 200. The light control layer 300 may include the first light shielding layer 310, a plurality of first color filters 320, a cover inorganic layer 330, a planarization layer 340, the second light shielding layer 350, and an overcoating layer 360.

According to one or more embodiments of the present disclosure, the first light shielding layer 310 may be commonly arranged in the first area A1 and the second area A2 (e.g., may cover and/or overlap the entirety of the first area A1 and the second area A2 as one common layer). The first light shielding layer 310 may be arranged to overlap the conductive pattern of the second conductive layer 240. The first light shielding layer 310 may be directly arranged on the sensor cover layer 250. The first light shielding layer 310 may prevent or reduce the reflection of external light by the second conductive layer 240.

A material constituting the first light shielding layer 310 is not particularly limited as long as the material absorbs light. The first light shielding layer 310 is a layer having a black color, and in one or more embodiments, the first light shielding layer 310 may include a black coloring agent. The black coloring agent may include black dye and/or black pigment. The black coloring agent may include carbon black, a metal such as chromium, or an oxide thereof.

The openings 310-OP may be defined in the first light shielding layer 310. FIG. 6A illustrates a shape of the first light shielding layer 310 arranged in the first areas A1 and the second areas A2 on a plane (e.g., in a plan view). Each of the openings 310-OP defined in the first areas A1 may have a circular shape. Areas of the openings 310-OP defined in the first areas A1 and areas of the openings 310-OP defined in the second areas A2 may be the same.

However, the present disclosure is not limited thereto, and an area of the opening 310-OP arranged in the first area A1 among the openings transmitting a light having a corresponding color may be greater than an area of the opening 310-OP arranged in the second area A2. For example, an opening 310-OP for a pixel in the first area A1 that transmits red light (or green light or blue light) may have the same area or may have a larger area relative to the area of an opening 310-OP for a pixel in the second area A2 that transmits red light (or green light or blue light, respectively).

Further, the shape of the openings 310-OP may be the same as the shape of the display openings 70-OP (see, e.g., FIG. 5A) defined in the pixel-defining film 70 (see, e.g., FIG. 5A) on a plane (e.g., in a plan view), but the present disclosure is not limited to one embodiment.

According to one or more embodiments of the present disclosure, the transmissive areas WPXAG1, WPXAG2, WPXAR, and WPXAB, through which a light generated in the first unit pixel WPX (see, e.g., FIG. 4A) passes, may be defined by the openings 310-OP of the first light shielding layer 310, which are defined in the first area A1.

The openings 310-OP defined in the second area A2 may overlap the transmissive areas NPXAG1, NPXAG2, NPXAR, and NPXAB, which are defined in the second unit pixel NPX (see, e.g., FIG. 4B), in one-to-one correspondence. The openings 310-OP may be defined by a side surface of the first light shielding layer 310.

The color filter layer 320 may include a (1-1)^{th} color filter W320G1 and a (1-2)^{th} color filter W320R that are arranged in the first area A1. Each of the (1-1)^{th} color filter W320G1 and the (1-2)^{th} color filter W320R may be arranged inside the opening 310-OP defined in the first area A1. The (1-1)^{th} color filter W320G1 may be to transmit light emitted from the (1-1)^{th} pixel WPXG1, and the (1-2)^{th} color filter W320R may be to transmit light emitted from the (1-2)^{th} pixel WPXR. The color filter layer 320 may include a (1-1)^{th} color filter that overlaps the (1-1)^{th} pixel WPXG2 and a (1-3)^{th} color filter that overlaps the (1-3)^{th} pixel WPXB, which are described in FIG. 4A.

The color filter layer 320 may include a (2-1)^{th} color filter N320G1 and a (2-2)^{th} color filter N320R that are arranged in the second area A2. Each of the (2-1)^{th} color filter N320G1 and the (2-2)^{th} color filter N320R may be arranged inside the opening 310-OP defined in the second area A2. The (2-1)^{th} color filter N320G1 may be to transmit light emitted from the (2-1)^{th} pixel NPXG1, and the (2-2)^{th} color filter N320R may be to transmit light emitted from the (2-2)^{th} pixel NPXR. The color filter layer 320 may include a (2-1)^{th} color filter that overlaps the (2-1)^{th} pixel NPXG2 and a (2-3)^{th} color filter that overlaps the (2-3)^{th} pixel NPXB, which are described in FIG. 4A.

The cover inorganic layer 330 may be commonly arranged in the first area A1 and the second area A2 (e.g., may cover and/or overlap the entirety of the first area A1 and the second area A2 as one common layer). The cover inorganic layer 330 may cover the color filter layer 320. The cover inorganic layer 330 may protect the color filter layer 320 and the first light shielding layer 310 from moisture and/or oxygen. The cover inorganic layer 330 may include a silicon nitride layer, a silicon oxynitride layer, a silicon oxide layer, a titanium oxide layer, an aluminum oxide layer, and/or the like.

The planarization layer 340 may be commonly arranged in the first area A1 and the second area A2 (e.g., may cover and/or overlap the entirety of the first area A1 and the second area A2 as one common layer). The planarization layer 340 may cover the first light shielding layer 310 and the color filter layer 320. The planarization layer 340 may include an organic material, and a planarization surface may be provided on an upper surface of the planarization layer 340. The planarization layer 340 may be formed by an inkjet process. In one or more embodiments, the planarization layer 340 may not be provided.

The overcoating layer 360 may be commonly arranged in the first area A1 and the second area A2 (e.g., may cover and/or overlap the entirety of the first area A1 and the second area A2 as one common layer). The overcoating layer 360 may cover the planarization layer 340. According to one or more embodiments of the present disclosure, in the first area A1, the overcoating layer 360 may be arranged on the planarization layer 340. For example, because the second light shielding layer 350 is not arranged in the first area A1, a lower surface of the overcoating layer 360 may be fully in contact with an upper surface of the planarization layer 340 in the first area A1 (e.g., the entire lower surface of the overcoating layer 360 may contact the upper surface of the planarization layer 340).

As illustrated in FIG. 5B, the light control layer 300 according to one or more embodiments of the present disclosure may include the second light shielding layer 350 arranged only in the second area A2. The second light shielding layer 350 may be arranged on the planarization layer 340 and may be covered by the overcoating layer 360.

The second light shielding layer 350 of the display device DD according to one or more embodiments of the present disclosure may be a functional layer arranged to emit light at a narrow viewing angle in the second mode that is the private mode. Thus, in the second mode, only the second unit pixels NPX (see, e.g., FIG. 4A) overlapping the second light shielding layer 350 may be driven. A plurality of light shielding patterns may be arranged in the second light shielding layer 350, and the pattern openings 350-OP may be defined in the light shielding patterns, respectively. Each of the pattern openings 350-OP may overlap a corresponding one of the openings 310-OP of the first light shielding layer 310, which is defined in the second area A2.

FIG. 6B illustrates a shape of the second light shielding layer 350 arranged in the second areas A2 on a plane (e.g., in a plan view). The second light shielding layer 350 may include the first pattern 350-P and the second pattern 350-S.

The first pattern 350-P may include the first light shielding pattern 350-G1, the second light shielding pattern 350-G2, the third light shielding pattern 350-R, the fourth light shielding pattern 350-B, the bridge patterns 350-C, and the connection pattern 350-I. The first light shielding pattern 350-G1, the second light shielding pattern 350-G2, the third light shielding pattern 350-R, and the fourth light shielding pattern 350-B may include the pattern openings 350-OP that overlap the openings 310-OP of the first light shielding layer 310 in one-to-one correspondence. For example, the first light shielding pattern 350-G1 may overlap the opening 310-OP corresponding to the (2-1)^{th} pixel NPXG1, the second light shielding pattern 350-G2 may overlap the opening 310-OP corresponding to the (2-1)^{th} pixel NPXG2, the third light shielding pattern 350-R may overlap the opening 310-OP corresponding to the (2-2)^{th} pixel NPXR, and the fourth light shielding pattern 350-B may overlap the opening 310-OP corresponding to the (2-3)^{th} pixel NPXB.

The first light shielding pattern 350-G1 may be spaced and/or apart (e.g., spaced apart or separated) from the second light shielding pattern 350-G2 in the first direction DR1. The third light shielding pattern 350-R may be spaced and/or apart (e.g., spaced apart or separated) from the first light shielding pattern 350-G1 in the first diagonal direction CDR1 and may be spaced and/or apart (e.g., spaced apart or separated) from the second light shielding pattern 350-G2 in the second diagonal direction CDR2.

The fourth light shielding pattern 350-B may be spaced and/or apart (e.g., spaced apart or separated) from the third light shielding pattern 350-R in the second direction DR2, may be spaced and/or apart (e.g., spaced apart or separated) from the first light shielding pattern 350-G1 in the second diagonal direction CDR2, and may be spaced and/or apart (e.g., spaced apart or separated) from the second light shielding pattern 350-G2 in the first diagonal direction CDR1.

The bridge patterns 350-C may be arranged between the light shielding patterns spaced and/or apart (e.g., spaced apart or separated) from each other within one second area A2. For example, the bridge patterns 350-C may be arranged between the light shielding patterns spaced and/or apart (e.g., spaced apart or separated) from each other in the first diagonal direction CDR1 and/or the second diagonal direction CDR2 and may connect the light shielding patterns to each other.

However, the present disclosure is not limited thereto, the first pattern 350-P may further include bridge patterns arranged between the light shielding patterns spaced and/or apart (e.g., spaced apart or separated) from each other in the first direction DR1 and/or the second direction DR2 within one second area A2, and the present disclosure is not limited to one embodiment.

The connection pattern 350-I may be a pattern that connects different second areas A2 spaced and/or apart (e.g., spaced apart or separated) from each other in the first direction DR1 or the second direction DR2. In one or more embodiments, the connection pattern 350-I may be a pattern that connects different second areas A2 whose corners are adjacent to each other, for example, in the first direction DR1 or the second direction DR2. For example, the connection pattern 350-I may be arranged between the second light shielding pattern 350-G2 arranged in the second area A2 on the left side and the first light shielding pattern 350-G1 arranged in the second area A2 on the right side as shown, for example, in FIG. 6B.

According to one or more embodiments of the present disclosure, in the light shielding patterns arranged inside the display area DA, patterns arranged in substantially the same second area A2 may be connected to each other, and the light shielding patterns arranged in the second areas A2 spaced and/or apart (e.g., spaced apart or separated) from each other (and/or adjacent to each other) in the first direction DR1 and/or the second direction DR2 may be connected to each other. Thus, the display device including the light shielding patterns may have an increased coupling force.

In one or more embodiments, each of the light shielding patterns 350-G1, 350-G2, 350-R, and 350-B may have a ring shape. Each of the light shielding patterns 350-G1, 350-G2, 350-R, and 350-B having a ring shape may be around (e.g., surround) the opening 310-OP on a plane (e.g., in a plan view).

An area of the pattern opening 350-OP defined in the second area A2 may be smaller than an area of the opening 310-OP of the first light shielding layer 310, which is defined in the second area A2. For example, an inner edge of each of the light shielding patterns 350-G1, 350-G2, 350-R, and 350-B may overlap the corresponding opening 310-OP for each respective pixel. Thus, the second unit pixels NPX (see, e.g., FIG. 4A) overlapping the second area A2 may have a narrower viewing angle than that of the first unit pixels WPX (see, e.g., FIG. 4A).

According to one or more embodiments of the present disclosure, the transmissive areas NPXAG1, NPXAG2, NPXAR, and NPXAB that transmit lights generated in the second unit pixel NPX (see, e.g., FIG. 4A) may be defined by the pattern openings 350-OP defined in the second light shielding layer 350.

In one or more embodiments, the pattern openings 350-OP may have the same area. However, the present disclosure is not limited thereto, and areas of the pattern openings 350-OP, through which different colored lights pass, may be different from each other, and the present disclosure is not limited to one embodiment.

The second light shielding layer 350 may be formed of substantially the same material as that of the first light shielding layer 310. Thus, the second light shielding layer 350 may prevent or reduce the reflection of external light and may include a black component that absorbs a light.

In one or more embodiments of the present disclosure, the second unit pixels NPX (see, e.g., FIG. 4A) may be driven in both (e.g., simultaneously) the first mode that is the normal mode and the second mode which is the private mode. In the second mode that is the private mode, the first unit pixels WPX (see, e.g., FIG. 4A) may not be driven. Thus, the second mode may display an image at a narrower viewing angle than that of the first mode.

Comparing FIG. 5A with FIG. 5B, the first area A1 may include the first light shielding layer 310 in which the openings 310-OP are defined and may not include (e.g., may exclude) the second light shielding layer 350. Thus, in the first mode, a light emitted from the (1-2)^{th} light-emitting element WOLR at a first angle AG1 and a second angle AG2 may be visually recognized by the user and an outsider who views the light from a high (steep) angle.

In contrast, the second area A2 may include the first light shielding layer 310 in which the openings 310-OP are defined and the second light shielding layer 350 in which the pattern openings 350-OP are defined. As described above, the area of the pattern openings 350-OP is smaller than the area of the openings 310-OP, and thus in the first mode and the second mode, a light emitted from a (2-2)^{th} light-emitting element NOLR at the first angle AG1 and the second angle AG2 may not be visually recognized by the outsider.

According to one or more embodiments of the present disclosure, if (e.g., when) the second light shielding layer 350 is formed together with the first light shielding layer 310, compared to a structure in which only the first light shielding layer 310 is formed, a narrower viewing angle may be exhibited. When a narrower viewing angle is formed, a strong private mode may be provided, and thus a display device DD having enhanced privacy protection may be provided.

FIG. 7A is a plan view illustrating a second light shielding layer, according to one or more embodiments of the present disclosure. FIG. 7B is an enlarged plan view of the area AA′ of FIG. 7A, according to one or more embodiments of the present disclosure. FIG. 7C is an enlarged plan view of the area BB′ of FIG. 7A, according to one or more embodiments of the present disclosure. FIG. 7A illustrates a shape of the second light shielding layer 350 in a plan view.

The second light shielding layer 350 may be arranged on the planarization layer 340. For convenience of description, the planarization layer 340 is indicated by a dotted line.

The second light shielding layer 350 may include the first pattern 350-P and the second pattern 350-S. The first pattern 350-P may include the first light shielding pattern 350-G1, the second light shielding pattern 350-G2, the third light shielding pattern 350-R, the fourth light shielding pattern 350-B, the bridge patterns 350-C, and the connection pattern 350-I. The description of the first pattern 350-P may be the same as the description of FIGS. 5A to 6B.

Referring to FIGS. 7A to 7C, the second light shielding layer 350 may include the second pattern 350-S and dummy patterns 350-D arranged in the non-display area NDA.

The second pattern 350-S may be around (e.g., surround) the first pattern 350-P. The second pattern 350-S may include first portions PS extending in the first direction DR1, second portions PL extending in the second direction DR2, and corner portions PC arranged between the first portions PS and the second portions PL.

The first portions PS may be spaced and/or apart (e.g., spaced apart or separated) from each other in the second direction DR2 with the display area DA interposed therebetween. The second portions PL may be spaced and/or apart (e.g., spaced apart or separated) from each other in the first direction DR1 with the display area DA interposed therebetween. The first portions PS may be relatively shorter than the second portions PL. According to one or more embodiments, the corner portions PC may have a set or predetermined curvature. Thus, corners of the second pattern 350-S may have rounded shapes.

The second pattern 350-S may be arranged along the non-display area NDA and may be around (e.g., surround) the light shielding patterns 350-G1, 350-G2, 350-R, and 350-B included in the first pattern 350-P. Thus, the second pattern 350-S may have a closed-line shape (a ring shape) arranged in the non-display area NDA.

According to one or more embodiments of the present disclosure, the second pattern 350-S may be connected to the light shielding patterns 350-G1, 350-G2, 350-R, and 350-B. Further, the second pattern 350-S may be patterned by substantially the same process as the first pattern 350-P. Thus, the second pattern 350-S may be arranged on the same layer as the first pattern 350-P and may include the same material.

The second pattern 350-S may overlap a bezel pattern of the window defining the external appearance of the display device DD and may not be visually recognized by the user.

According to one or more embodiments of the present disclosure, the second pattern 350-S may be connected to the first pattern 350-P arranged inside the display area DA. The second pattern 350-S may be connected to at least one of the light shielding patterns 350-G1, 350-G2, 350-R, and 350-B, the bridge patterns 350-C, and/or the connection patterns 350-I. Thus, the first pattern 350-P and the second pattern 350-S may be provided in the form of an integral pattern (one body).

When there is no second pattern 350-S connected to the first pattern 350-P, a coupling force of one of the light shielding patterns 350-G1, 350-G2, 350-R, and 350-B, the bridge patterns 350-C, and the connection patterns 350-I arranged at a boundary between the display area DA and the non-display area NDA is smaller than a coupling force of adjacent patterns, and thus a lifting phenomenon occurs at the boundary between the display area DA and the non-display area NDA, which may degrade display quality.

According to one or more embodiments of the present disclosure, because the patterns arranged on the second light shielding layer 350 are provided as an integral pattern, patterns arranged adjacent to the boundary between the display area DA and the non-display area NDA among patterns included in the first pattern 350-P may be prevented from being lifted or the likelihood of lifting may be reduced. Accordingly, quality of the display device DD that may be operated in the two modes may be improved.

The second light shielding layer 350 according to one or more embodiments may include the dummy patterns 350-D arranged in the non-display area NDA. The dummy patterns 350-D may be defined as patterns arranged in the non-display area NDA among the patterns included in the first pattern 350-P and obtained by removing a portion of a shape of the patterns included in the first pattern 350-P. For example, the dummy patterns 350-D may be in the non-display area NDA, but may continue in the pattern of the first pattern 350-P from the display area DA, as shown in FIG. 7B. Thus, the dummy patterns 350-D may have a shape substantially similar to and/or the same as a portion of the shape of the first pattern 350-P in the display area DA. The dummy patterns 350-D may be arranged between the patterns included in the first pattern 350-P and the second pattern 350-S. However, the present disclosure is not limited thereto, the dummy patterns 350-D may not be provided, and the second pattern 350-S may be directly connected to the patterns included in the first pattern 350-P.

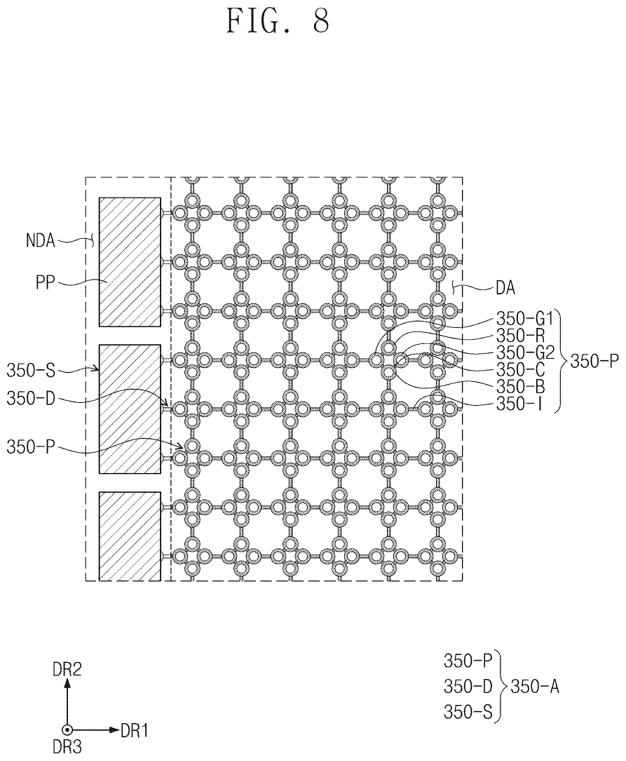

FIG. 8 is a plan view illustrating a portion of the second light shielding layer according to one or more embodiments of the present disclosure. The same and/or similar reference numerals are used for the same and/or similar components as those described in FIGS. 4A to 7C, respectively, and duplicated descriptions thereof may not be provided.

Referring to FIG. 8, a second light shielding layer 350-A may include the first pattern 350-P, a dummy pattern 350-D, and the second pattern 350-S. According to one or more embodiments, the second pattern 350-S may include a plurality of patterns PP. The plurality of patterns PP may be arranged in the non-display area NDA along the boundary between the display area DA and the non-display area NDA. When the patterns arranged in the first direction DR1 among the patterns included in the first pattern 350-P are defined as a group pattern (e.g., where the group pattern includes the first patterns 350-P arranged in a row of second areas A2 along the first direction DR1), three group patterns may be connected to the one pattern PP. However, two or more group patterns may be connected to the one pattern PP, but the present disclosure is not limited to one embodiment.

According to one or more embodiments, if (e.g., when) a defect occurs in one of the patterns included in the first pattern 350-P, only the group patterns connected to the defective pattern and the one pattern PP connected thereto may be removed. Accordingly, the defective pattern among the patterns included in the first pattern 350-P may be easily removed and re-formed or may undergo a repair process.

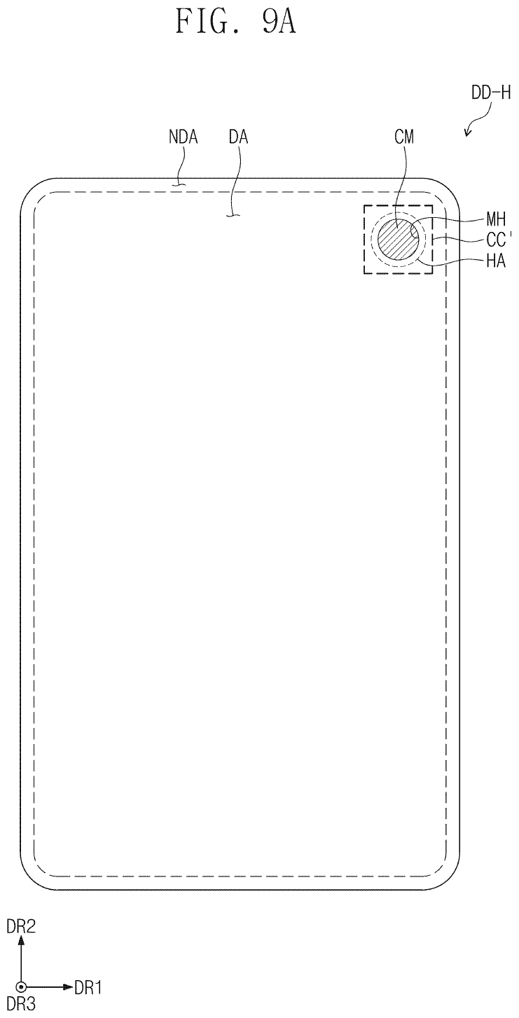

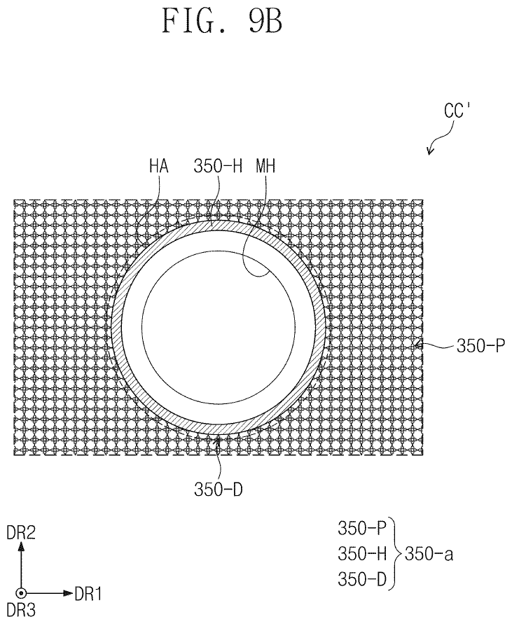

FIG. 9A is a plan view illustrating a display panel according to one or more embodiments of the present disclosure. FIG. 9B is an enlarged plan view of the area CC′ of FIG. 9A, according to one or more embodiments of the present disclosure. The same and/or similar reference numerals are used for the same and/or similar components as those described in FIGS. 4A to 7C, and duplicated descriptions thereof may not be provided.

Referring to FIG. 9A, a display device DD-H according to one or more embodiments may include a hole area HA, the display area DA, and the non-display area NDA. The hole area HA may be arranged inside the display area DA.

A module hole MH overlapping the hole area HA may be defined in the display panel DP of the display device DD-H according to one or more embodiments. The hole area HA may be formed through the base layer 110, the circuit layer 120, the light-emitting element layer 130, the encapsulation layer 140, and the sensor layer 200. The module hole MH may be covered by the light control layer 300 and the window.

The display device DD-H according to one or more embodiments may further include a camera module CM. The camera module CM may overlap the module hole MH. At least a portion of the camera module CM may be arranged inside the module hole MH or under the display panel DP described in FIG. 3.

According to one or more embodiments, as the camera module CM is arranged inside the display area DA, a separate area for arranging the camera module CM may be reduced. Accordingly, an unnecessary increase in the non-display area NDA may be prevented or reduced.

Referring to FIG. 9B, the second light shielding layer 350-A according to one or more embodiments may include the first pattern 350-P, the second pattern 350-S (see, e.g., FIG. 7A), and a third pattern 350-H (also referred to as a “hole pattern”). A description of the first pattern 350-P and the second pattern 350-S (see, e.g., FIG. 7A) may be the same as the described with reference to FIGS. 4A to 7C.

The third pattern 350-H may be arranged in the hole area HA. The third pattern 350-H may have a ring shape around (e.g., surrounding) the module hole MH. The third pattern 350-H may be connected to the patterns included in the first pattern 350-P arranged in the display area DA. Further, the third pattern 350-H may be patterned by substantially the same process as the first pattern 350-P. Thus, the third pattern 350-H may be arranged on the same layer as the first pattern 350-P and may include the same material.

According to one or more embodiments, even if (e.g., when) the module hole MH defined inside the display area DA is included, the patterns included in the third pattern 350-H and the first pattern 350-P are provided as an integral pattern, and thus a phenomenon in which patterns arranged adjacent to a boundary between the display area DA and the hole area HA are lifted may be prevented or reduced. Accordingly, the quality of the display device DD-H that may be operated in the two modes may be improved.

The second light shielding layer 350-A according to one or more embodiments may include the dummy patterns 350-D arranged in the non-display area NDA. The dummy patterns 350-D may be defined as patterns that are arranged in the hole area HA among the patterns included in the first pattern 350-P and are obtained by removing the portion of the shape of the patterns included in the first pattern 350-P. For example, the dummy patterns 350-D may be in the hole area HA, but may continue in the pattern of the first pattern 350-P from the display area DA, as shown in FIG. 9B. Thus, the dummy patterns 350-D may have a shape substantially similar to and/or the same as a portion of the shape of the first pattern 350-P in the display area DA. The dummy patterns 350-D may be arranged between the patterns included in the first pattern 350-P and the third pattern 350-H. However, the present disclosure is not limited thereto, the dummy patterns 350-D may not be provided, and the third pattern 350-H may be directly connected to the patterns included in the first pattern 350-P.

According to one or more embodiments of the present disclosure, patterns arranged on a light shielding layer are provided as an integral pattern, and thus a phenomenon in which patterns arranged adjacent to a boundary between a display area and a non-display area are lifted may be prevented or reduced. Accordingly, display quality and reliability of a display device that may be operated in two modes may be improved.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic device, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a display panel comprising
a base substrate having a display area and a non-display area adjacent to the display area, the display area having a first area and a second area,
a first unit pixel in the first area,
a second unit pixel in the second area, and
an encapsulation layer covering the first unit pixel and the second unit pixel; and
a light control layer comprising
a first light shielding layer in the first area and the second area, the first light shielding layer defining openings to transmit light generated by the first unit pixel and the second unit pixel,
color filters arranged in the openings, and
a second light shielding layer on the first light shielding layer,
wherein the second light shielding layer comprises:
light shielding patterns defining pattern openings that respectively overlap the openings in the second area; and
at least one outer pattern in the non-display area and adjacent to the light shielding patterns.

2. The display device of claim 1, wherein the light shielding patterns and the outer pattern are an integral pattern in which the light shielding patterns and the outer pattern are arranged on the same layer and connected to each other.

3. The display device of claim 2, wherein the light shielding patterns and the outer pattern comprise the same material.

4. The display device of claim 1,
wherein the first unit pixel comprises
(1-1)^{th} pixels to emit a first color light and spaced from each other in a first direction,
a (1-2)^{th} pixel to emit a second color light different from the first color light and spaced from the (1-1)^{th} pixels in diagonal directions that are at an angle relative to the first direction, and
a (1-3)^{th} pixel to emit a third color light different from the first color light and the second color light, spaced from the (1-2)^{th} pixel in a second direction intersecting the first direction, and spaced from the (1-1)^{th} pixels in the diagonal directions, and
wherein the second unit pixel comprises
(2-1)^{th} pixels to emit the first color light and spaced from each other in the first direction,
a (2-2)^{th} pixel to emit the second color light and spaced from the (2-1)^{th} pixels in the diagonal directions, and
a (2-3)^{th} pixel to emit the third color light, spaced from the (2-2)^{th} pixel in the second direction, and spaced from the (2-1)^{th} pixels in the diagonal directions.

5. The display device of claim 4, wherein the first unit pixel comprises a plurality of first unit pixels, and the second unit pixel comprises a plurality of second unit pixels,
wherein four different second unit pixels of the plurality of second unit pixels are arranged adjacent to a first unit pixel of the plurality of first unit pixels in the diagonal directions, and
wherein four different first unit pixels of the plurality of first unit pixels are arranged adjacent to a second unit pixel of the plurality of second unit pixels in the diagonal directions.

6. The display device of claim 4, wherein the second area comprises a plurality of second areas,
wherein the light shielding patterns are arranged inside one second area of the plurality of second areas and are spaced from each other in the diagonal directions, and
wherein each of the light shielding patterns has a ring shape.

7. The display device of claim 5, wherein the second light shielding layer further comprises bridge patterns arranged between the light shielding patterns arranged inside the second area.

8. The display device of claim 5, wherein the second area comprises a plurality of second areas,
wherein the second light shielding layer further comprises connection patterns connecting the light shielding patterns arranged on different second unit pixels of the plurality of second unit pixels, and
wherein one end of the connection pattern is connected to a light shielding pattern of the light shielding patterns in one second area of the plurality of second areas, and the other end of the connection pattern is connected to a light shielding pattern of the light shielding patterns in another second area of the plurality of second areas.

9. The display device of claim 4, wherein each of the (1-1)^{th} pixels, the (1-2)^{th} pixel, the (1-3)^{th} pixel, the (2-1)^{th} pixels, the (2-2)^{th} pixel, and the (2-3)^{th} pixel comprises a first electrode, a second electrode, and a light-emitting pattern between the first electrode and the second electrode.

10. The display device of claim 9, wherein the display panel comprises a pixel-defining film defining display openings exposing at least a portion of each of the first electrodes of the (1-1)^{th} pixels, the (1-2)^{th} pixel, the (1-3)^{th} pixel, the (2-1)^{th} pixels, the (2-2)^{th} pixel, and the (2-3)^{th} pixel,
wherein the light-emitting patterns of the (1-1)^{th} pixels, the (1-2)^{th} pixel, the (1-3)^{th} pixel, the (2-1)^{th} pixels, the (2-2)^{th} pixel, and the (2-3)^{th} pixel are arranged in the display openings, and
wherein the openings and the pattern openings overlap the display openings.

11. The display device of claim 1, wherein an area of the pattern openings is smaller than an area of the openings.

12. The display device of claim 11, wherein each of the openings has one of a circular shape or an elliptical shape.

13. The display device of claim 11, wherein each of the pattern openings has a circular shape.

14. The display device of claim 1, wherein the base substrate defines a hole area inside the display area,
wherein the display panel defines a module hole passing through the display panel and overlapping the hole area, and
wherein the display device further comprises a camera module overlapping the module hole.

15. The display device of claim 14, wherein the second light shielding layer further comprises a hole pattern around the module hole, and
wherein the hole pattern is an integral pattern in which the hole pattern and the light shielding patterns are arranged on the same layer and are connected to each other.

16. The display device of claim 15, wherein the second light shielding layer further comprises dummy patterns arranged in the non-display area adjacent to a boundary between the display area and the non-display area and in the hole area adjacent to a boundary between the hole area and the display area and having a shape that is the same as a portion of a shape of the light shielding patterns, and
wherein the dummy patterns are arranged between the light shielding patterns and the outer pattern and between the light shielding patterns and the hole pattern.

17. The display device of claim 1, wherein the light control layer comprises:
a planarization layer covering the color filters, the second light shielding layer being on the planarization layer; and
an overcoating layer on the planarization layer and covering the second light shielding layer.

18. The display device of claim 17, wherein the display panel further comprises a sensor layer directly on the encapsulation layer, the sensor layer comprising insulating layers and conductive layers between the insulating layers, and
wherein the first light shielding layer is directly on an uppermost insulating layer among the insulating layers.

19. An electronic device comprising:
a display device comprising:
a display panel comprising
a base substrate having a display area and a non-display area adjacent to the display area, the display area having a first area and a second area,
a first unit pixel in the first area,
a second unit pixel in the second area, and
an encapsulation layer covering the first unit pixel and the second unit pixel; and
a light control layer comprising
a first light shielding layer in the first area and the second area, the first light shielding layer defining openings to transmit light generated by the first unit pixel and the second unit pixel,
color filters arranged in the openings, and
a second light shielding layer on the first light shielding layer, wherein the second light shielding layer comprises:
light shielding patterns defining pattern openings that respectively overlap the openings in the second area; and
at least one outer pattern in the non-display area and being adjacent to the light shielding patterns.

20. The electronic device of claim 19, wherein the electronic device is a mobile phone, a tablet, a smart watch, a laptop, a computer, or a smart television.
